(19) United States
(12) Patent Application Publication
(10) Pub. No.: US 2017/0241016 A1
(43) Pub. Date: Aug. 24, 2017

(54) Process for making low-resistivity CVC

(71) Applicant: Fantom Materials, Inc., Lihu, HI (US)

(72) Inventors: Lauren Bolton, Lihue, HI (US); Kenneth Paul Hoffman, Kapaa, HI (US)

(73) Assignee: Fantom Materials, Inc., Lihu, HI (US)

(21) Appl. No.: 14/757,279

(22) Filed: Dec. 12, 2015

(51) Int. Cl. C23C 16/448; G02B 5/08; C23C 16/56; C23C 16/01; C23C 16/32

(52) U.S. Cl. CPC C23C 16/4486; C23C 16/01; C23C 16/325; C23C 16/56; G02B 5/0833

(57) ABSTRACT

A process for making low resistivity CVC silicon carbide. Applicants have developed a better process for adding nitrogen to silicon carbide which has the safety economic advantages of doping with N₂ with the ease of N₂ release advantages of using NH₃. Preferred embodiments of the present invention include a NH₃ generator with a source of H₂ and a source of N₂ and an arc discharge apparatus adapted to produce NH₃ gas from a combination of the H₂ and N₂ sources.

### CROSS REFERENCE TO RELATED APPLICATIONS

This application is a Continuation-In-Part of Utility application Ser. No. 14/121,049 filed Jul. 14, 2014, which is incorporated herein by reference and claims the benefit of Provisional Application Ser. No. 62/124,231 filed Dec. 12, 2014.

### FIELD OF THE INVENTION

The present invention relates to silicon carbide products and to processes for making low resistivity CVC.

### BACKGROUND OF THE INVENTION

### Silicon Carbide

Silicon carbide, also known as carborundum, is a rare earth element, existing naturally in minute quantities only in the form of moissanite in certain types of meteorites and corundum deposits and kimberlite. Virtually all the silicon carbide sold in the world is synthetic. Early experiments in the synthesis of silicon carbide were conducted during the 1800's using a variety of source materials and processes. Wide scale production of silicon carbide as we know it today is credited to Edward Goodrich Acheson in 1890. Acheson patented the method for making silicon carbide powder and developed the electric batch furnace by which SiC is still made today. Acheson formed The Carborundum Company to manufacture SiC in bulk, initially for use as an abrasive, although the material he formed varied in purity. Pure silicon carbide can be made by three primary processes and one patented process. The first is known as the Lely method whereby silicon carbide powder is sublimated onto substrates comprised of the same constituents and re-deposited at cooler temperatures to form SiC. The second method of preparation is by thermal decomposition of a polymer, poly(methylsilane), under an inert atmosphere at low temperatures. The third method, known as the chemical vapor deposition process (CVD), involves thermal decomposition of a high purity chemical precursor on a substrate surface. The fourth method of production is a process patented by Trex Enterprises Corporation called the chemical vapor composite (CVC®) process.

Silicon carbide exists in a large number of crystalline forms all of which are variations of the same chemical compound. Alpha silicon carbide (α-SiC), the most common form of silicon carbide, has a hexagonal crystal structure. Silicon carbide produced using CVD processes typically have a face-centered cubic crystal structure referred to as a beta silicon carbide. Silicon carbide produced using the CVC process is typically a mixture of alpha silicon carbide and beta silicon carbide.

Silicon carbide has a theoretical density of 3.21 g/cm³ and is chemically inert. SiC has a high melting point (2730° C.), low coefficient of thermal expansion (CTE) and no phase transitions that would cause discontinuities in thermal expansion, making it an ideal material for high temperature and optical applications.

The Applicant's employer (Trex Enterprises Corporation) is the assignee of two patents (U.S. Pat. Nos. 5,154,862 and 5,348,765, both of which are incorporated by reference herein) covering a unique process for making silicon carbide, known as the CVC process or the CVC SiC® process (CVC® and CVC SiC® are registered trademarks of Trex Enterprises Corporation). The following description of Trex's CVC SiC process is provided in the '765 patent by reference to FIG. 1 as follows:

A preferred method of forming composite articles according to the invention is practiced using a reactor system 10 illustrated in FIG. 1 which includes a reactor 20 to which a mixture of particles or fibers and reactor gas is supplied along a line 21 from a solid phase feeder 22 and a reactant gas supply 24. The reactor 20 may be a quartz reactor whose outer wall 26 is wrapped with an induction coil 28 connected to an electoral power source 30, and may be cooled by fans (not shown) and by cooling water introduced through appropriate lines 31 and 32 extending into end flanges 33 and 34. A vacuum pump 35 for evacuating the reactor 20 is connected to one branch 36 of an exhaust line 38 and a second branch 40 directs exhaust gases from reactor 20 to a scrubber 44. Also connected to the reactor 20 are a motor 50 and a shaft 52 employed to rotate a substrate 54 within reactor 20 to insure even codeposition of materials on the substrate according to the method of the invention as set forth in more detail hereinafter.

In CVC SiC an aerosol of solid micron-scale SiC particles is entrained within a reactant chemical vapor precursor such as MIS mixed with hydrogen gas as described in the two patents referred to above (which have been incorporated by reference) and injected into a high temperature furnace. The aerosol mixture reacts at high temperature to form solid, high purity CVC SiC on a heated graphite substrate. The chemical process is analogous to chemical vapor deposition (CVD), which similarly uses a chemical vapor precursor, but without the added SiC particles. The key consequence of adding solid particles to the reaction stream is a unique grain structure that results in a fully dense, virtually stress-free material, all as described in the above patents. Thus, CVC SiC can be:
grown over 5× faster than conventional CVD
scaled to very large sizes (up to 1.45 m diameter)
manufactured thickness of at least 63 mm
deposited to near net shape
machined to thin dimensions with reduced risk of fracture

Other notable advantages of CVC silicon carbide include very high stiffness, high thermal conductivity, low thermal expansion, low density and high specific stiffness.

### High Quality Silicon Carbide Parts for Semiconductor Fabrication

There is a need for low resistivity high quality silicon carbide parts for use in semiconductor fabrication. It is known that resistivity can be reduced by the addition of trace amounts of Group III elements (such as boron, aluminum, etc or Group V elements (such as nitrogen, phosphorus, etc). These semiconductor products needing low electrical resistance include plasma hocus rings in semiconductor processing equipment where resistivity requirements are less than 0.1 ohm-cm. Radiation hard optics also benefit from lower resistivity by eliminating charge effects. Also, improved electrical conductivity enables parts to be fabricated by electrical discharge machining (EMD), which require electrical resistivity under about 50 ohm-cm.

Common sources of nitrogen are N_{2 a}nd NH₃. Of these sources NH₃ is usually preferred since the nitrogen atom is more easily freed as compared to the nitrogen molecule N₂. However NH₃ is considerably more toxic than N₂.

What is needed is an improved process for adding nitrogen to silicon carbide.

### SUMMARY OF THE INVENTION

The present invention provides a process for making low resistivity CVC silicon carbide. Applicants have developed a better process for adding nitrogen to silicon carbide which has the safety economic advantages of doping with N₂ with the ease of N₂ release advantages of using NH₃. Preferred embodiments of the present invention include a NH₃ generator with a source of H₂ and a source of N₂ and an arc discharge apparatus adapted to produce NH₃ gas from a combination of the H₂ and N₂ sources. A substrate is installed in a CVD reactor. The substrate need to be compatible with a thermally activatable reactant gas to produce chemical vapor deposition vapors and other reaction products. The reactant gas is introduced into the reactor along with a gas stream from the NH3 generator, and the reactant gas and the gas stream from the NH₃ generator is thermally activate such that the reactant gas reacts to produce CVD vapors and the gas stream from the NH₃ generator produces atomic nitrogen. As a result materials from the CVD vapors and atomic nitrogen are deposited on the substrate with the atomic nitrogen being dispersed within the materials from the CVD vapors.

In preferred embodiments CVD reactor include a source of solid particles or fibers and the reactor is a CVC reactor and the solid particles or fibers is introduced into the reactor along with the gas stream from the NH3 generator and/or the reactant gas. The arc discharge apparatus include a spark plug, an ignition coil a MSD ignition control element and an ignition tester and it may be powered by an automobile battery.

### BRIEF DESCRIPTION OF THE DRAWINGS

FIG. 1 is a prior art drawing depicting a CVC SiC system.

FIG. 2 is a drawing describing an arc discharge apparatus.

FIG. 3 shows an apparatus for making low resistivity CVC SiC.

### DETAILED DESCRIPTION OF PREFERRED EMBODIMENTS

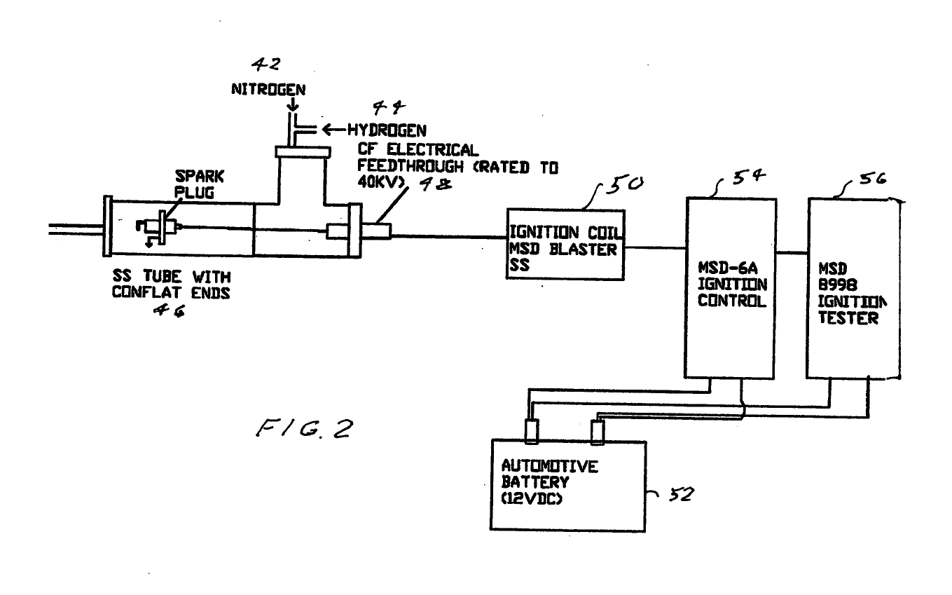

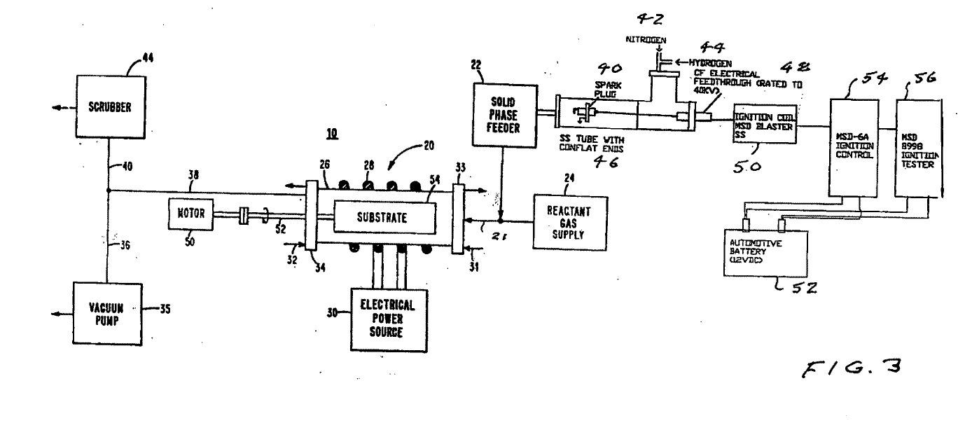

Applicants preferred process for adding nitrogen to silicon carbide can be describe by reference to FIGS. 2 and 3. FIG. 2 shows a technique for utilizing nitrogen (N₂) and hydrogen (H₂) source gasses in molecular form to produce NH₄ which more readily gives up atomic nitrogen the course of chemical deposition processes. The atomic nitrogen feed equipment was constructed from commercial-off the-shelf-components. The premise was to flow N₂ and H₂ into the apparatus and utilize arc discharge to crack the strongly covalently bonded N₂ and H₂ molecules, which then react to form toxic NH₃. The NH₃ is substantially more efficient source of atomic nitrogen than N₂. The nitrogen feed equipment includes spark plug 40, N₂ source 42, H₂ source 44, SS tube with conflat ends 46, CF electrical feed-through (rated to 40 KV) 48, Ignition coil 50, 12-volt auto battery 52, MSD-ga Ignition control 54 and MSD ignition tester 56.

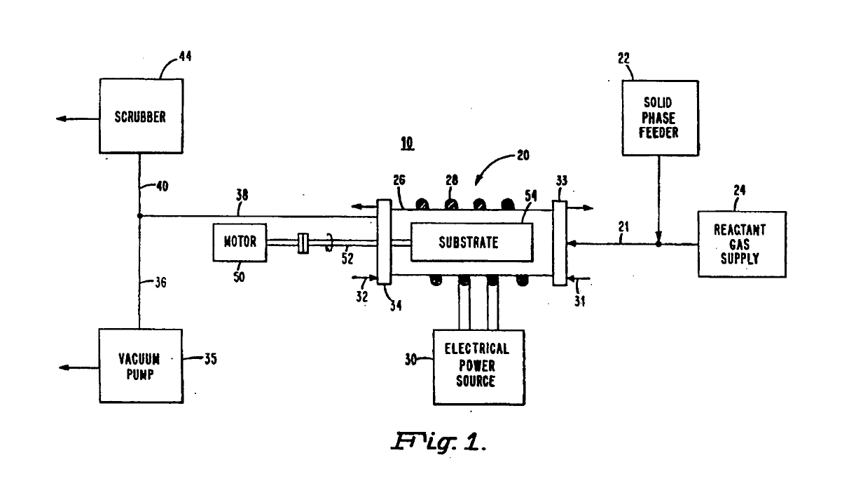

FIG. 3 is a combination of FIG. 2 and prior art FIG. 1 where the output of the equipment shown in FIG. 2 replaces apportion of the reactant gas supply shown in FIG. 1.

### Experimental Results

To achieve improvements in the nitrogen doping process for low resistivity CVC SiC®, Trex designed and built an arc discharge system, shown schematically in the FIG. 1 below. The premise was to flow N₂ and H₂ into the apparatus and utilize the arc discharge to crack the strongly covalently bonded N₂ and H₂ molecules, which then react to form ammonia. Ammonia produces a more efficient nitrogen dopant source to incorporate an n-type dopant into the CVC lattice.

The arc discharge apparatus was constructed using commercial-off-the-shelf automotive spark plug and ignition coils, shown in FIG. 2. The apparatus was assembled and bench tested prior to installation into Applicants' reactor. Trex installed the arc discharge apparatus into its 0.4 m (16″) reactor and defined an experimental test plan (Table 1) for low resistivity CVC SiC® development. Trex machined the nitrogen-doped material that was made during these runs into 101 mm×3 mm×3 mm bars and utilized an in-house four point measurement to determine resistivity.

The lowest resistivity achieved in the test plan was 0.3 ohm-cm (by the four point probe method described above), which is significantly lower than the approximately 0.5-1.0 ohm-cm achieved in the past with nitrogen doping CVC SiC® without the arc discharge. Adjustments to the hydrogen flow along with modest increases in nitrogen and spark frequency could enable the 0.1 ohm-cm target for semiconductor applications. This avenue was considered during the next phase of experimentation.

Several improvements were made to arc discharge apparatus for the next phase of experimentation: an oil-cooled coil was installed which maintained a lower operating temperature, stainless steel (SS) wool was added as a catalyst to promote gas ionization and thereby encouraging ammonia production, and a larger arc discharge chamber was construction to allow a higher volume of N₂ and H₂ to be ionized, thereby increasing the volume of ammonia generated.

Samples from each run were sent to a certified lab for volume resistivity measurements along with an un-doped CVC SiC control sample (TK18474). Test methods ASTM D4496 (AC measurement) and D257 (DC measurement) were used. Results were as follows:

TK18474 (control): 428 ohm-cm (DC), 882 ohm-cm (AC)

TK16422: 62 ohm-cm (DC), 85 ohm-cm (AC)

TK16423 (doped powder): 99 ohm-cm (DC), 142 ohm-cm (AC)

In order to further reduce volume resistivity the CVC SiC® doping process was moved to the 0.46 m (18″) reactor, which allowed for higher N₂/H₂ gas volumes, thereby theoretically permitting higher ammonia production.

Trex also opted to experiment with a modified CVC® manufacturing process. Trex retrofitted the 0.46 m (18″) reactor to flow NH₃ (ammonia) directly into the chamber in the form of a 1% NH₃ in Ar gas mixture. The rationale was to determine the relative effectiveness of 1% NH₃ as the dopant gas versus generating ammonia in situ with the arc discharge apparatus. Run TK18620 was conducted using baseline CVC SiC® run parameters plus 5 slm 1% NH₃-Ar. Preliminary run analysis suggests that the density of this material is lower than Trex's routine CVC SiC®, 3.0 g/cm³ vs. 3.21 g/cm³ respectively. The cause of this is still under evaluation. Samples from this run were sent to the same certified lab for volume resistivity analysis, along with another conductive CVD SiC sample with a resistivity advertised as <1 ohm-cm. ASTMs D4496 and D257 were used. Results are as follows:

Trex (TK18620): 27 ohm-cm

Third party sample: 98-140 ohm-cm

In parallel material from TK18620 was tested at the third party source's lab (certification unknown). Results indicate a volume resistivity value of 0.006 ohm-cm.

In the interim since the provisional application was filed Applicant submitted samples from its most recent low resistivity CVC SiC run to Orton Ceramic (a certified materials testing lab) along with commercially available low resistivity CVD SiC from a third party source (this third party source supplies the semiconductor industry with most of their CVD SiC material). Orton Ceramic used ASTM D4496 and ASTM D257 test methodologies to determined the volume resistivity of Applicants low resistivity CVC SiC and the commercially available low resistivity CVD SiC. Results are shown in the table below:

Results illustrate two important points:
1. Trex's low resistivity CVC SiC material has up to 100× lower volume resistivity than credible competition based on two different test methods.
2. The third party low res CVD SiC has a published resistivity value of less than 1 ohm-cm using method ASTM D4496, which is inconsistent with the certified lab results Trex obtained on their material.

To further qualify the material, a sample from TK18620 was sent to an EDM (electrical discharge machining) shop for wire EDM testing. EDM is a standard machining method used on conductive (low resistivity) materials and is significantly less expensive than diamond grinding, which is the standard machining method for non-conductive, hard ceramics like silicon carbide. The EDM shop indicated that TK18620 material cut beautifully.

What can be deduced from these results is that Trex's low resistivity CVC SiC material is superior to credible competition and is more suitable for semiconductor low resistivity and ultralow resistivity applications than said third party source.

One other point of note: the aforementioned third party source has stopped making their CVD SiC altogether. The semiconductor industry will soon find itself in a material source crisis. Trex's low resistivity CVC SiC is poised to become the semiconductor industry's material of choice.

Applicants' conclusion is Trex's material is clearly of lower resistivity than credible competition and these results validate our methodology for low resistivity CVC SiC material.

### Variations

Persons skilled in the chemical vapor deposition art will recognize that many variation to the specific embodiments described above are possible. For example, many changes in the parameters disclosed can be made to increase the amount of nitrogen incorporated into the CVC SiC which will have a direct effect on the electrical resistance. The processes describe herein can also be applied to standard chemical vapor deposition. Therefore, the scope of the present invention should be determined by the appended claims.

What is claimed is:

1. A process for making low-resistivity CVC SiC and low resistivity CVD SiC comprising the following steps:
A) provide a NH₃ generator comprising:
1) a source of H₂ and a source of N₂
2) an arc discharge apparatus adapted to produce NH₃ gas from a combination of the H₂ and N₂ sources,
B) install in a CVD reactor a substrate compatible with a thermally activatable reactant gas to produce chemical vapor deposition vapors and other reaction products,
C) introduce the reactant gas into the reactor along with a gas stream from the NH3 generator,
D) thermally activate the reactant gas and the gas stream from the NH₃ generator such that the reactant gas reacts to produce CVD vapors and the gas stream from the NH₃ generator produces atomic nitrogen,
E) deposit materials from the CVD vapors and atomic nitrogen on the substrate with the atomic nitrogen dispersed within the materials from the CVD vapors.

2. The process as in claim 1 wherein the CVD reactor comprises a source of solid particles or fibers and the reactor is a CVC reactor.

3. The process as in claim 2 wherein the solid particles or fibers is introduced into the reactor along with the gas stream from the NH3 generator.

4. The process as in claim 1 wherein the NH3 generator comprises a spark plug, an ignition coil a MSD ignition control element and an ignition tester.

5. The process as in claim 4 wherein the NH3 generator is powered by an automotive battery.
